(19) United States
(12) Patent Application Publication
(10) Pub. No.: US 2005/0174735 A1
(43) Pub. Date: Aug. 11, 2005

(54) High performance cooling systems

(76) Inventors: Nagui Mankaruse, Huntington Beach, CA (US); Magda Mankaruse, Huntington Beach, CA (US)

Correspondence Address: NAGUI MANKARUSE, P.O. BOX 1215, SUNSET BEACH, CA, 90714, US

(21) Appl. No.: 11/036,816

(22) Filed: Jan. 15, 2005

Related U.S. Application Data
(63) Continuation-in-part of application No. 10/647,846, filed on Aug. 26, 2003.

(51) Int. Cl. H05K 7/20

(52) U.S. Cl. 361/695

(57) ABSTRACT

High Performance cooling systems for cooling a heat source is disclosed. The cooling systems can be air cooling system, liquid cooling system, or space radiation cooling system. Air cooling system includes at least high performance cold plate or cold plates, plenum, liquid pump, and liquid to air heat exchanger. Liquid cooling system includes at least high performance cold plate or cold plates, plenum, liquid pump, and liquid to liquid heat exchanger. Space radiation cooling system includes at least high performance cold plate or cold plates, plenum, liquid pump, and space radiator. Several coolant fluids are available and can be used as a primary system coolant depending on the application.

The present invention relates generally to cooling systems, and more practically, to three cooling systems that are; air cooling liquid cooling, and radiation cooling. The cooling systems to be used with semiconductor devices and other heat-generating components and modules. The three cooling modes are for systems used in cooling semiconductor devices and modules.

### BACKGROUND OF THE INVENTION

1. Field of the Invention

The invention relates generally to systems cooling; air-cooling systems liquid-cooling systems, and radiation cooling systems for high power dissipating electronic components or modules mounted on printed circuit boards or on a cold plate directly and more specifically a cost effective, high performance, high reliable cooling systems.

2. Description of Related Art

Generally, electronic devices are provided with a large number of heat-generating components and modules. As a result, in order to prevent the interior of the device from overheating, a cooling system has to be introduced. In recent years a cooling system for efficiently cooling the individual printed circuit boards that carry high heat dissipating electronic semi-conductor components or the semi-conductor components or modules mounted on the conductive surface of a cold plate. Conventionally, the cooling systems used in electronic devices are of two types: forced-air types and forced-liquid types. [GIG.] FIG. 1 A is a diagram showing a conventional forced-air type cooling system 500, FIG. 1B is a diagram showing a conventional forced-liquid type cooling system 600.

As shown in FIG. 1 A, the air-cooled cooling system 500 has a heat sink 503 made from conductive material having a high rate of heat transmission. such as aluminum or copper is provided on a heated part 501. The heat sink 503 is provided with a multiplicity of fins in order to increase the radiative effect. In the cooling system 500 a flow of air forcibly created by a fan 505 cools these fins and so cool the heated part 501.

Additionally, as shown in FIG. 1B, the liquid-cooled cooling system 600 has thermally conductive cold plates 603 provided in direct contact with the heated part 601. These cold plates 603 are positioned so as to contact a pipe 604 through which a liquid coolant 609 circulates opposite the heated part 601. When the liquid coolant 609 passes through the heat exchanger 607 it is heat exchanged and cooled, so the cold plats 603 can also be cooled and, accordingly, the heated part 601 is also cooled. This liquid-cooled cooling system 600 has a pump 605 and a heat exchanger 607 having a fan 608 to forcibly cool the heated part 601.

However, the above-described air-cooled cooling system 500 uses air to cool the heated member 501, so the rate of heat transmission is very low and the radiative effect is poor[.] .

The liquid-cooled cooling system 600 described above, although it has good thermal conductivity, nevertheless still uses a pump 605 and a fan 608 and so is subject to the same disadvantages as those pertaining to the air-cooling system 500 described above, namely heat transmission is relatively low and radiative effect is poor.

The prior art teaches the use [the] of heat dissipation devices in forming cooling systems for cooling electrical and electronic semi-conductor devices and modules, but does not teach such systems having the features of high performance, low cost, low specific weight, specific volume per unit power dissipation cooled and ease of manufacture. The present invention fulfills these needs and provides further related advantages as described in the following summary.

### SUMMARY OF THE INVENTION

It is a general object of the present invention to provide a high capacity cooling systems in which high power dissipation of high heat flux semiconductor devices or modules is accomplished using compact, cost effective cooling systems for different applications.

The apparatus and method of this invention provide cost-effective, high performance and modular way of producing cooling systems configuration that is capable of being produced and assembled through putting together core modules. The core modules are produced by mass production techniques or purchased from specialized producers and are ready to form the cooling system assembly. Substantial costs and delays in fabrication are minimized in addition to increase in reliability, which lower the breakdown risk level or increase the mean time between failures (MTBF). In addition a high heat dissipation of individual semiconductor devices or modules is achieved with low specific weight, volume and cost per unit power dissipation.

To realize the foregoing advantages, the invention in one form comprises a cold plate assembly for cooling heat sources on a printed circuit board, or individual semi-conductor components or modules mounted directly on cold plate i.e., the high power dissipating electronic components or modules. The cold plate assembly used is the high performance cold plate U.S. Pat. No. 6,411,512 or any other high performance cold plates with high power dissipating cooling capacity as required that is:

The air cooling system comprises four modules including: high performance cold plate or cold plates, plenum, liquid circulating pump, and liquid to air heat exchanger.

The liquid cooling system comprises four modules including: high performance cold plate or cold plates, plenum, liquid circulating pump, and liquid to liquid heat exchanger.

The space radiation cooling system comprises four modules including: high performance cold plate or cold plates, plenum, liquid circulating pump, and space radiator to exchange the heat to the outer space by radiation.

### BRIEF DESCRIPTION OF THE DRAWINGS

The accompanying drawings illustrate the present invention. In such drawings:

FIG. 1A is a cross-sectional view of a prior art forced-air type cooling system;

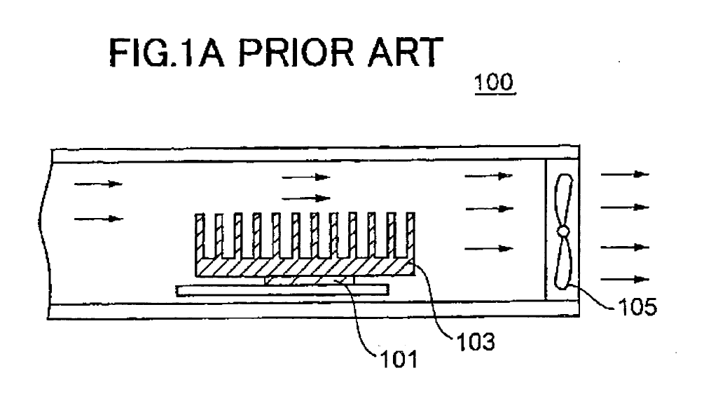

FIG. 1B is a cross-sectional view of a prior art liquid type cooling system;

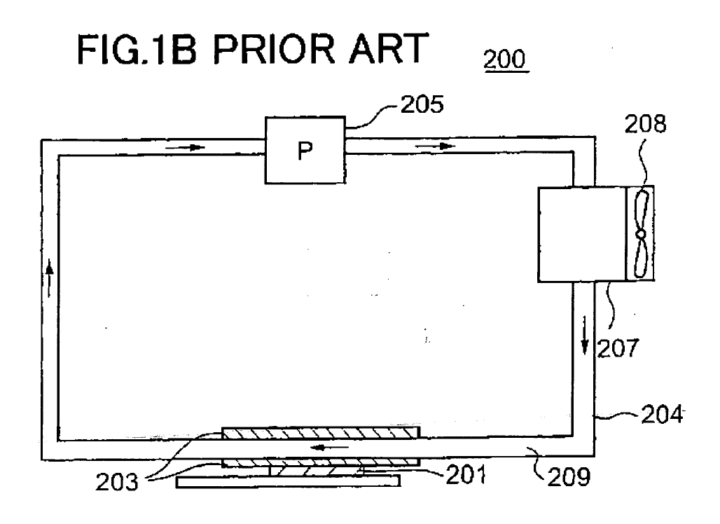

FIG. 2 is an air cooling system schematic;

FIG. 3 is a liquid cooling system schematic;

FIG. 4 is a space radiation cooling system schematic;

FIG. 5 is a top plan view of a cold plate assembly according to the invention;

FIG. 6 is an enlarged cross-sectional view of the cold plate assembly attached to a printed circuit board shown taken along line 2-2 of FIG. 5;

FIG. 7 is a top plan view of a cold plate assembly using individual heat pipes;

FIG. 8 is an enlarged cross-sectional view of a cold plate assembly attached to a printed circuit board shown taken along line 4-4 of FIG. 7;

FIG. 9 is a cross-sectional view of a cold plate assembly using individual heat pipes attached to a printed circuit board shown taken along line 5-5 of FIG. 7; and

FIG. 10 is a block diagram illustrating steps employed according to one embodiment of the method of the present invention.

### DETAILED DESCRIPTION OF THE INVENTION

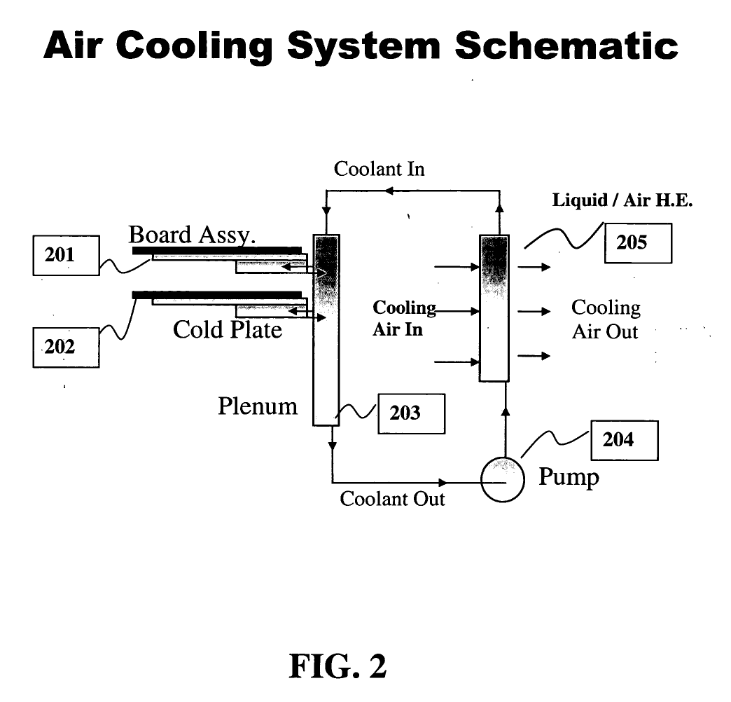

The above described drawing figures illustrate the invention in at least one of its preferred embodiments, which is further defined in detail in the following description. Referring to the FIG. 2, ‘Air Cooling System Schematic’ five modules are employed; A conductive high performance cold plate 201, of the present invention;

A printed circuit board 202, with semiconductor devices ‘heat source’ mounted on the printed circuit board or heat dissipating semi-conductor devices, modules. The printed circuit board or heat dissipating module or modules are thermally attached to the cold plate or cold plates;

A plenum 203, to supply the cold plate or cold plates with cold coolant and collect returned hot coolant from two separated paths;

A circulating liquid pump 204 to receive the hot returned coolant from the cooled cold plate or cold plates through the plenum and deliver it to;

Liquid to air heat exchanger 205, in which the returned hot coolant is cooled by ambient air through exiting the liquid to air heat exchanger cold coolant to be re-circulated back to the plenum 203 and then to enter the cold plate or cold plates.

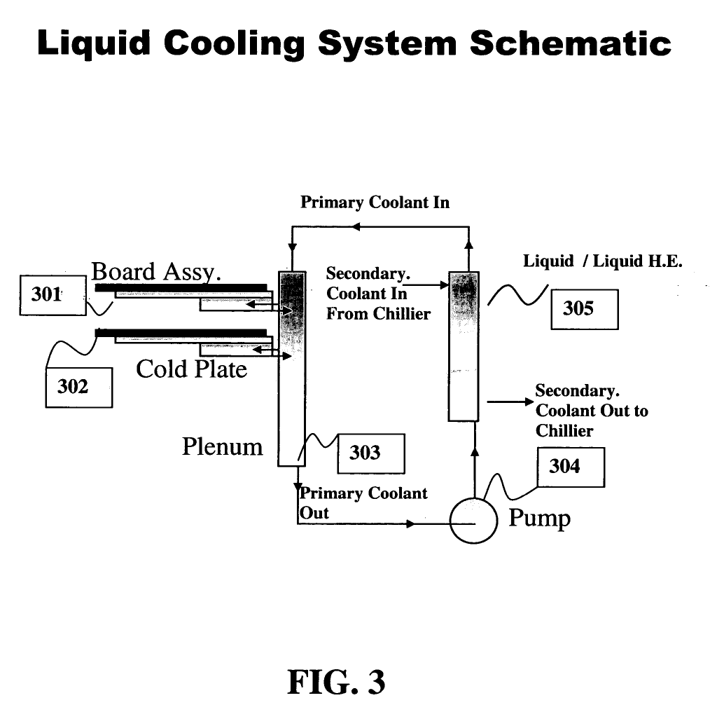

Referring to the FIG. 3, ‘Liquid Cooling System Schematic’ five modules are employed;

A conductive high performance cold plate 301, of the present invention;

A printed circuit board 302, with semiconductor devices ‘heat source’ mounted on the printed circuit board or heat dissipating modules. The printed circuit board or heat dissipating semi-conductor devices, module or modules are thermally attached to the cold plate or cold plates;

A plenum 303, to supply the cold plate or cold plates with cold coolant and collect returned hot coolant from two separated paths;

A circulating liquid pump 304 to receive the hot returned coolant from the cooled cold plate or cold plates through the plenum and deliver it to;

Liquid to liquid heat exchanger 305, in which the returned hot coolant is cooled by a secondary coolant through the exiting liquid to liquid heat exchanger cold coolant to be re-circulated back to the plenum 303 and then to enter the cold plate or cold plates.

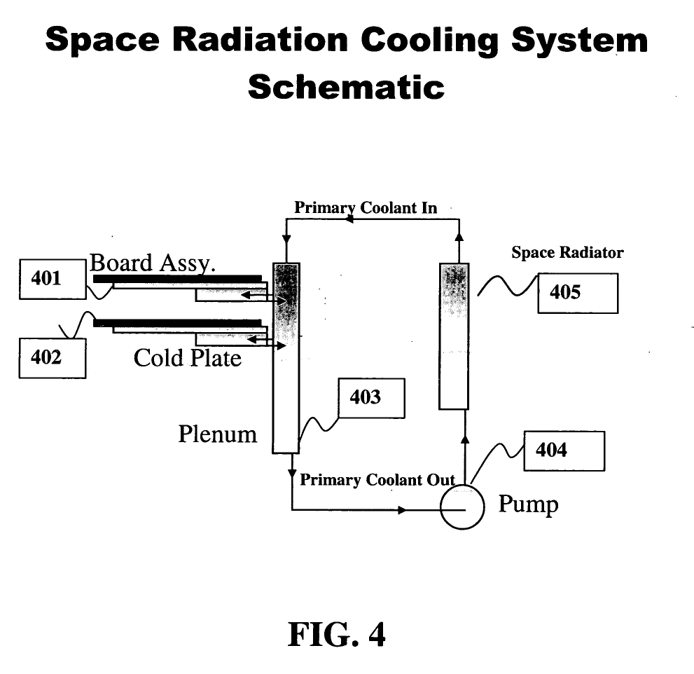

Referring to the FIG. 4, ‘Space Radiation Cooling System Schematic’ five modules are employed;

A conductive high performance cold plate 401, of the present invention;

A printed circuit board 402, with semiconductor devices ‘heat source’ mounted on the printed circuit board or heat dissipating modules. The printed circuit board or heat dissipating semi-conductor devices, module or modules are thermally attached to the cold plate or cold plates;

A plenum 403, to supply the cold plate or cold plates with cold coolant and collect returned hot coolant from two separated paths;

A circulating liquid pump 404 to receive the hot returned coolant from the cooled cold plate or cold plates through the plenum and deliver it to; space radiator 405, in which the returned hot coolant is cooled by cold space radiator and exiting cold coolant to be re-circulated back to the plenum 403 and then to enter the cold plate or cold plates.

System primary coolants can be water, Ethylene Glycol Water, Polyalphaolyfin ‘PAO’, Ammonia, Methanol, Nitrogen or any other coolant that can accommodate the system and temperature limits and requirement.

A conductive cold plate 25 of the present invention employs an easily manufactured modular construction made of three modules or elements. The three modules including a thermally conductive base 2, a heat pipe assembly 20, and compact heat exchanger 14 are described below.

A thermally conductive base 2 comprises a rectangular shaped plate of thermally conductive material, and provides a circuit board engagement interface. The interface is formed with a series of recesses that mirror the surface component topology of a circuit board 1, and a standoff 10 for mounting the cold plate 25 to the board 1. This thermally conductive base 2 is preferably made from machined aluminum alloy 6061 T6. In case of mass production to further reduce the cost of this module, die case aluminum alloy, brass or high conductivity polymer composite can be used.

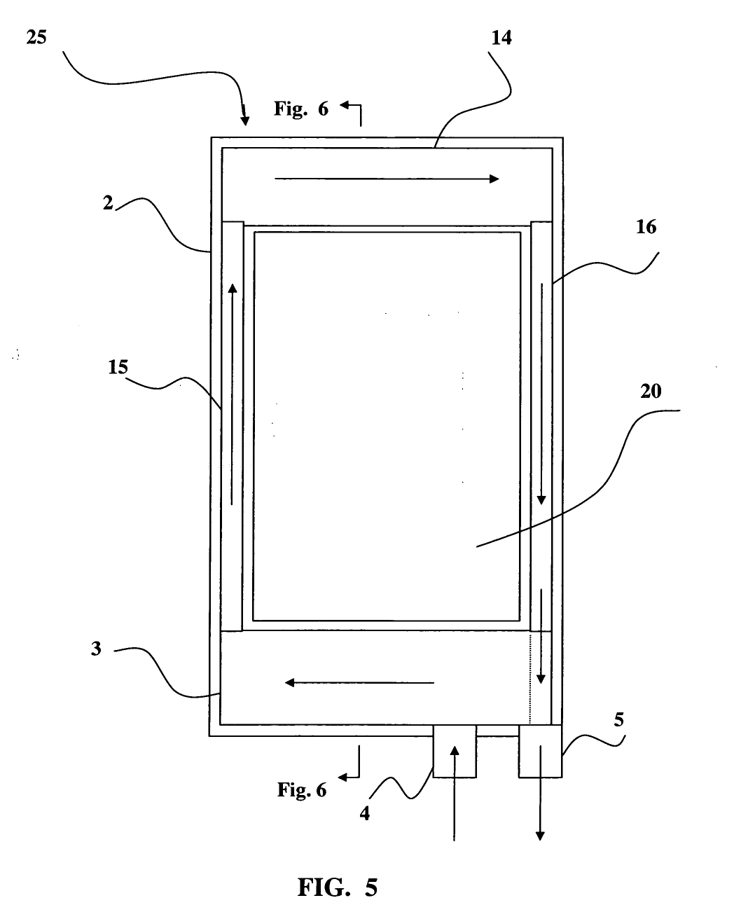

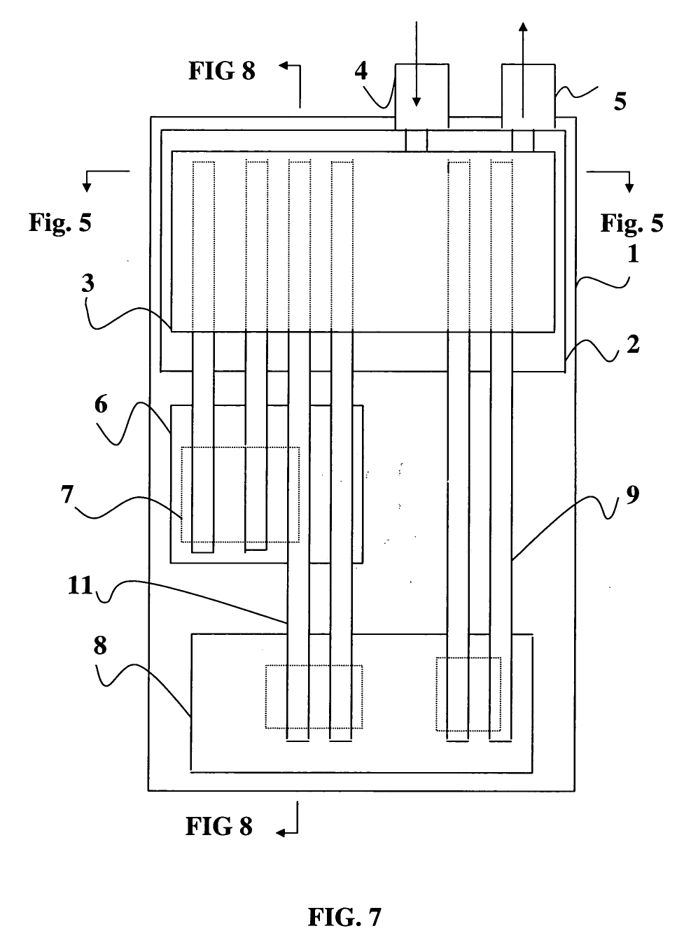

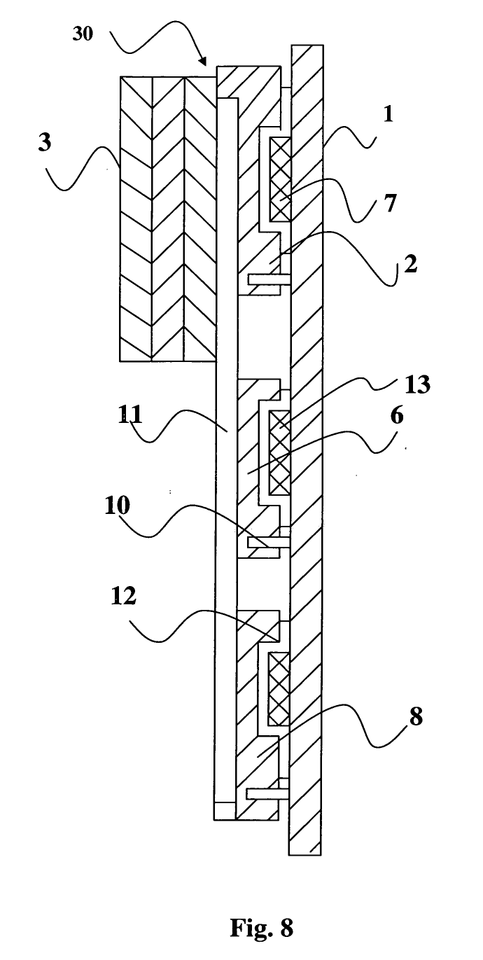

A heat pipe assembly 20 is preferably constructed as a thermal plane utilizing embedded copper/water heat pipes 9 & 11 sandwiched between two outer aluminum plates. The heat pipes thermal plane utilizes embedded heat pipes to carry the heat from components (the heat source) to the heat sink (heat exchangers) with a typical source to sink temperature difference of 20 degrees centigrade or less. While cooling at both edges is recommended for maximum heat pipe thermal plane performance, single edge cooling is possible with lower performance. Operation is sensitive to orientation of the heat pipes 9, shown in FIG. 7 and FIG. 8. A heat pipe 9 is a heat transfer device with an extremely high effective thermal conductivity. The heat pipe thermal plane 20, shown in FIG. 5, and heat pipes 9 shown in FIG. 7 are selected depending on the cooling system parameters to carry the heat from the electronic components through the base 2 to the cooling fluid in the heat exchanger 14. When using two compact heat exchangers at the edges of the cold plate base 2, cold plate performance is maximized due to maximum performance of heat pipe thermal plane. Single edge cooling using one heat exchanger is possible with slight de-rated performance. The efficiency of the cold plate 25 is dependent on mounting orientation as noted previously.

Common heat pipe types used are wicked, pulsating or loop heat pipes.

Heat pipes are evacuated vessels typically circular in cross section which are back filled with a quantity of a working fluid and they are totally passive as used to transfer heat from a source (electronic components) to a sink (heat exchangers) with minimal temperature gradient or to isothermalize a surface.

A Pulsating Heat Pipe or PHP consists of a plain meandering tube of capillary dimensions with many U-turns. In contrast to a conventional heat pipe, there is no additional capillary structure inside the tube. There are two ways to arrange the tube: open loop and closed loop. As the names suggest, in a closed loop structure, the tube is joined end-to-end. The tube is first evacuated and then filled partially with a working fluid, which distributes itself naturally in the form of liquid-vapor plugs and slugs inside the capillary tube. One end of this tube bundle receives heat, transferring it to the other end by a pulsating action of the liquid-vapor/bubble-slug system. There may exist an optional adiabatic zone in between. Also, one or more flow-direction control check valves may be introduced at suitable locations to augment the performance.

Capillary Pumped Loops and Loop Heat pipes are two-phase thermal control devices that work passively by means of capillary, forces, removing heat from a source and transporting it to a condenser (or radiator) to dissipate the heat. Capillary forces are generated in the evaporator, driving the working fluid, which works at its pure state, responsible for the heat transport. The working fluid is evaporated and as the CPL and LHP are natural thermal diodes, the vapor can only flow towards the condenser by the vapor line. Upon reaching the condenser, the working fluid condenses back to liquid, returning to the evaporator by the liquid line. In the case of LHP, coupled to the capillary evaporator, there is a two-phase reservoir.

Common heat pipe fluids used are ammonia, water, acetone, and methanol.

With reference to the figures, preferably a heat exchanger 3 and 14 is disposed at one or both opposite ends of heat pipe assembly 20. Preferably, the one or two heat exchangers are either laminated or finned. Moreover, preferably the heat exchanger is made of aluminum or copper and sized to accommodate the heat dissipation capacity of the printed circuit board. The flow rate of flow of the cooling fluid required is determined in proportion to the heat removal capacity of the cold plate 25, and a junction temperature range is maintained for the cooled electronic components mounted on the printed circuit board. With reference to FIG. 5, where two heat exchangers are provided, preferably, both are connected together with two aluminum or copper pipes 15 and 16 to transmit the cooling fluid. The pipes are connected to the inlet and outlet of the heat exchangers. The path of the cooling fluid is from an inlet quick disconnect 4 to the lower heat exchanger 3, then to pipe 15 and through the upper heat exchanger 14 to the pipe 16, and finally, out through the quick disconnect 5.

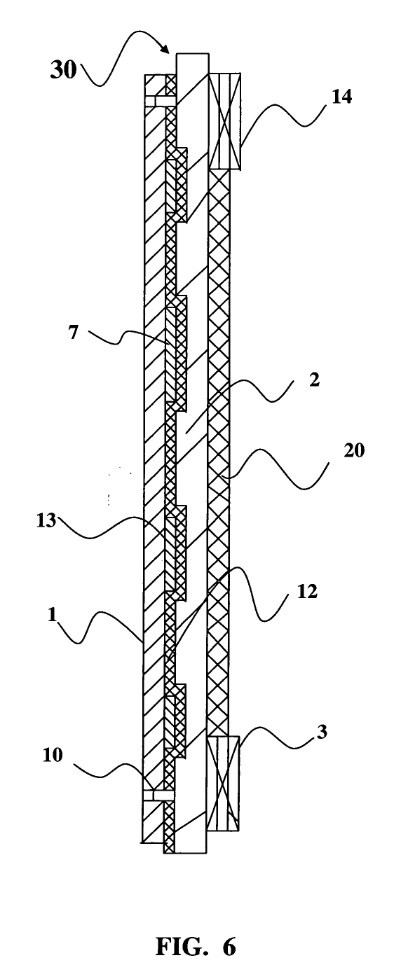

Referring to FIG. 6 the three module cold plate base 2, heat pipe thermal plane 20, and heat exchangers 3 and 14 are assembled together using high thermal conductive adhesives or any other thermally conductive bonding technique on the cold plate base outer surface. A template or fixture (not shown) is used to accurately locate the three modules in place relative to the controlling dimensions in the assembly process of the cold plate 25. The circuit board 1, with electronic component item 13, to be cooled is mounted on printed circuit board 1, and gap filler 35 is placed between the circuit board 1 and base plate 2. The circuit boards cooled by the cold plate in this invention are not limited in size, since heat pipe thermal plane or individual heat pipes can be custom designed to accommodate the cold plate size to cool the circuit board electronic components. Also the heat transmission capacity of the heat pipe thermal plane 20 can be customized to maximize the capacity and performance by changing the length, width and thickness of the heat pipe thermal plane 20. With reference to FIG. 7, the working fluid in the heat pipe thermal plane 20 can be of different types and, similarly the individual heat pipes 9 can be of different sizes (diameter, length, etc.) to accommodate the cooling capacity and the dimensions of the assembly. In the industry there are standard sizes of the heat pipe thermal plane 20 predesigned and available for production orders. In the case of using a heat pipe thermal plane, the use of the standard size of the heat pipe thermal plane reduces the cost of this module in the cold plate of this invention over the use of customized heat pipe thermal planes.

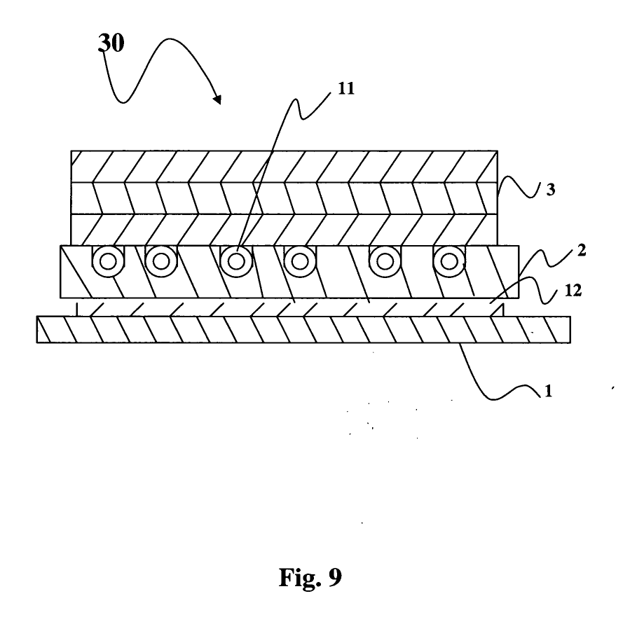

Referring now to FIGS. 7-9, the cold plate 25 of the present invention, generally employs a highly manufacturable modular construction, including a thermally conductive base, individual heat pipes, and plural heat exchangers. The cold plate 25 includes a rectangular shaped base plate of thermally conductive material such as aluminum, brass or high conductive polymer composite, having a circuit board engagement interface. The interface is formed with a series of recesses that mirror the surface component topology of the circuit board, with thermally conductive gap filler material (not shown). Reference numeral 3 refers to a laminate or finned heat exchanger. Reference numerals 4 and 5 refer to quick disconnects for the cooling fluid entering and exiting the heat exchanger. Reference numeral 7 refers to an electronic component to be cooled. Reference numeral 9 refers to the heat pipes. Reference numeral 2 refers to a thermally conductive base. Reference numeral 12 refers to a gap filler material. Reference numeral 10 refers to an alignment pin.

With reference to FIGS. 7-9, in an additional embodiment of the present invention, the three modules of the cold plate assembly are a cold plate base 2, individual heat pipes defining a heat pipe assembly 20, and one or more heat exchangers 3. The three modules are assembled together using brazing material like thermally conductive adhesive or soldering material or any other thermally conductive bonding technique. The individual heat pipes are bonded to the thermally conductive base's outer surface, by providing cavities to house the individual heat pipes. The heat exchanger 3 then is bonded to the cold plate base 2 using thermally conductive bonding material. A template or fixture is used to accurately locate the three modules in place relative to the controlling dimensions in the assembly process of the cold plate.

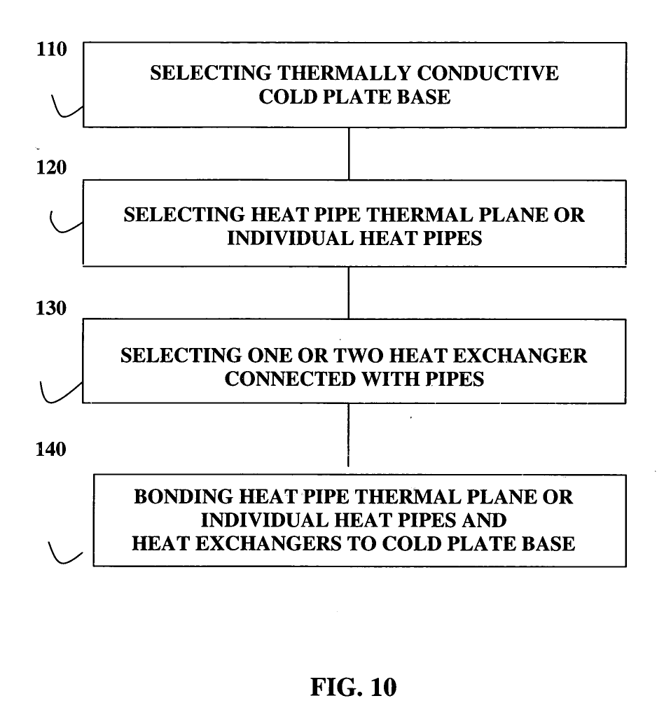

Referring now to FIG. 10, the structure of the cold plate assembly 25 enables the implantation of relatively straightforward assembly steps. Manufacturing the cold plate begins in step 110, with selecting a thermally conductive plate to define the base. Either casting or machining the profile of the topology on the far side forms the base. Then selecting the heat pipe thermal plane or individual heat pipes at step 120. Selecting the compact heat exchanger with the pipes in step 130.

Once the three main modules are selected, bonding them together as shown in FIGS. 5-9 makes the assembly of the cold plate step 140. Using a thin layer of high thermal conductive adhesive makes the bond. While the inventor has determine bonding using high thermally conductive adhesive offers the preferred results, other known processes may be employed without damaging the heat pipe thermal plane or the individual heat pipes.

Assembling the cold plate includes the base, the heat pipe thermal plane or individual heat pipes and the heat exchangers. The thermal capacity of transmitting the heat as determined by the main parameters of the heat pipe thermal plane or individual heat pipes. For a properly designed heat pipe thermal plane or individual heat pipes, depending on parameters, capacity for transmitting heat energy can handle applications with peak thermal flux range of more than 80 watts/square centimeter at the interface. Effective the thermal conductivity of the heat pipe thermal plane or individual heat pipes can virtually range over several multiples the effective thermal conductivity of copper depending on the parameters of the heat pipes used. The compact heat exchanger capacity for removing the heat to the cooling fluid is determined by the selected heat exchangers capacity. This defines the temperature level and the cooling capacity of the cold plate.

The cooling of high-power printed circuit boards is accomplished in this invention with cold plates mounted with the engagement interface positioned directly on the electronic component surface. Thermal putty interface material gap filler applied at the circuit board-to-cold plate interface junction ensures diminished air gaps to maximize the cooling effect of the cold plate.

1- Air cooling system using at least a liquid pump, a liquid to air heat exchanger and a cold plate assembly for cooling a component or module or a component or module on a circuit board assembly, considered a heat source, said cold plate assembly comprising:
a heat pipe assembly or a heat pipe including at least one heat pipe adapted for internally circulating a first thermally conductive fluid for carrying heat dissipated from the heat source;
at least one compact heat exchanger engaging and thermally connected to said heat pipe assembly, said heat exchanger adapted for internally circulating a second thermally conductive fluid includes an inlet for receiving said second thermally conductive fluid and an outlet for emitting said second thermally conductive fluid, and for carrying heat dissipated from said heat pipe assembly.

2- The cooling system of claim 1 using a cold plate assembly. The cold plate assembly for cooling this heat source, said cold plate assembly further comprising:
a thermally conductive base engaging said heat pipe assembly for being affixed to an electrical component or module or a circuit board with electrical components or modules considered a heat source.

3- The cooling system of claim 1 using a cold plate assembly. The cold plate assembly for cooling this heat source, said cold plate assembly further comprising:
a thermally conductive base engaging said heat pipe assembly for being affixed to an electrical component or module or a circuit board with electrical components or modules considered a heat source, said thermally conductive base including a plurality of recesses sized and configured for receipt of this heat source.

4- The heat pipe assembly of claim 1 is constructed as a heat pipe thermal plane assembly or a heat pipe thermal plane including at least one internal heat pipe adapted for internally circulating a first thermally conductive fluid for carrying heat dissipated from this heat source.

5- The heat pipe assembly of claim 1 is constructed as a pulsating heat pipe assembly or a pulsating heat pipe including at least one pulsating heat pipe adapted for internally circulating a first thermally conductive fluid for carrying heat dissipated from this heat source.

6- The heat pipe assembly of claim 1 is constructed as a loop heat pipe assembly or a loop heat pipe including at least one loop heat pipe or capillary pumped loop heat pipe adapted for internally circulating a first thermally conductive fluid for carrying heat dissipated from this heat source.

7- Liquid cooling system using at least a liquid pump, a liquid to liquid heat exchanger and a cold plate assembly for cooling a component or module or a component or module on a circuit board assembly, considered a heat source, said cold plate assembly comprising:
a heat pipe assembly or a heat pipe including at least one heat pipe adapted for internally circulating a first thermally conductive fluid for carrying heat dissipated from the heat source;
at least one compact heat exchanger engaging and thermally connected to said heat pipe assembly, said heat exchanger adapted for internally circulating a second thermally conductive fluid includes an inlet for receiving said second thermally conductive fluid and
an outlet for emitting said second thermally conductive fluid. and for carrying heat dissipated from said heat pipe assembly.

8- The cooling system of claim 7 using a cold plate assembly. The cold plate assembly for cooling this heat source, said cold plate assembly further comprising:
a thermally conductive base engaging said heat pipe assembly or heat pipe for being affixed to an electrical component or module or a circuit board with electrical components or modules considered a heat source.

9- The cooling system of claim 7 using a cold plate assembly. The cold plate assembly for cooling this heat source, said cold plate assembly further comprising:
a thermally conductive base engaging said heat pipe assembly for being affixed to an electrical component or module or a circuit board with electrical components or modules considered a heat source, said thermally conductive base including a plurality of recesses sized and configured for receipt of this heat source.

10- The heat pipe assembly of claim 7 is constructed as a heat pipe thermal plane assembly or a heat pipe thermal plane including at least one internal heat pipe adapted for internally circulating a first thermally conductive fluid for carrying heat dissipated from this heat source.

11- The heat pipe assembly of claim 7 is constructed as a pulsating heat pipe assembly or a pulsating heat pipe including at least one pulsating heat pipe adapted for internally circulating a first thermally conductive fluid for carrying heat dissipated from this heat source.

12- The heat pipe assembly of claim 7 is constructed as a loop heat pipe assembly or a loop heat pipe including at least one loop heat pipe or capillary pumped loop heat pipe adapted for internally circulating a first thermally conductive fluid for carrying heat dissipated from this heat source.

13- Radiation cooling system using at least a liquid pump, a liquid to radiator heat exchanger and a cold plate assembly for cooling a component or module or a component or module on a circuit board assembly, considered a heat source, said cold plate assembly comprising:
a heat pipe assembly or a heat pipe including at least one heat pipe adapted for internally circulating a first thermally conductive fluid for carrying heat dissipated from the heat source;
at least one compact heat exchanger. engaging and thermally connected to said heat pipe assembly, said heat exchanger adapted for internally circulating a second thermally conductive fluid includes an inlet for receiving said second thermally conductive fluid and an outlet for emitting said second thermally conductive fluid, and for carrying heat dissipated from said heat pipe assembly.

14- The cooling system of claim 13 using a cold plate assembly. The cold plate assembly for cooling this heat source, said cold plate assembly further comprising:
a thermally conductive base engaging said heat pipe assembly for being affixed to an electrical component or module or a circuit board with electrical components or modules considered a heat source.

15- The cooling system of claim 13 using a cold plate assembly. The cold plate assembly for cooling this heat source, said cold plate assembly further comprising:
a thermally conductive base engaging said heat pipe assembly or heat pipe for being affixed to an electrical component or module or a circuit board with electrical components or modules considered a heat source, said thermally conductive base including a plurality of recesses sized and configured for receipt of this heat source.

16- The heat pipe assembly of claim 13 is constructed as a heat pipe thermal plane assembly or a heat pipe thermal plane including at least one internal heat pipe adapted for internally circulating a first thermally conductive fluid for carrying heat dissipated from this heat source.

17- The heat pipe assembly of claim 13 is constructed as a pulsating heat pipe assembly or a pulsating heat pipe including at least one pulsating heat pipe adapted for internally circulating a first thermally conductive fluid for carrying heat dissipated from this heat source.

18- The heat pipe assembly of claim 13 is constructed as a loop heat pipe assembly or a loop heat pipe including at least one loop heat pipe or capillary pumped loop heat pipe adapted for internally circulating a first thermally conductive fluid for carrying heat dissipated from this heat source.
